(19) United States
(12) Patent Application Publication
(10) Pub. No.: US 2008/0217603 A1
(43) Pub. Date: Sep. 11, 2008

(54) Hot electron transistor and semiconductor device including the same

(76) Inventors: Youichi Takeda, Ora-gun (JP); Hideaki Fujiwara, Hashima-shi (JP); Shinya Naito, Anpachi-gun (JP)

Correspondence Address: MCDERMOTT WILL & EMERY LLP, 600 13TH STREET, N.W., WASHINGTON, DC, 20005-3096, US

(21) Appl. No.: 12/010,764

(22) Filed: Jan. 29, 2008

(30) Foreign Application Priority Data
Jan. 31, 2007 (JP) JP2007-021730
Dec. 28, 2007 (JP) JP2007-341214

(51) Int. Cl. H01L 29/08

(52) U.S. Cl. 257/29; 257/E29.033

(57) ABSTRACT

A hot electron transistor includes a collector layer, a base layer, an emitter layer, a collector barrier layer formed between the collector layer and the base layer, and an emitter barrier layer formed between the base layer and the emitter layer. An energy barrier between the emitter barrier layer and the emitter layer does not substantially exist and the height of an energy barrier of the collector barrier layer is lower than the height of an energy barrier of the emitter barrier layer.

### CROSS-REFERENCE TO RELATED APPLICATIONS

The priority application numbers JP2007-21730, Hot Electron Transistor and Semiconductor Device including the Same and Method of Fabricating Hot Electron Transistor, Jan. 31, 2007, Yoichi Takeda, Hideaki Fujiwara, Shinya Naito, JP2007-341214, Hot Electron Transistor and Semiconductor Device including the Same, Dec. 28, 2007, Yoichi Takeda, Hideaki Fujiwara, Shinya Naito, upon which this patent application is based are hereby incorporated by reference.

### BACKGROUND OF THE INVENTION

1. Field of the Invention

The present invention relates to a hot electron transistor and a semiconductor device including the same, and more particularly, it relates to a hot electron transistor formed with a collector barrier layer and an emitter barrier layer and a semiconductor device including the same.

2. Description of the Background Art

A hot electron transistor formed with a collector barrier layer and an emitter barrier layer is known in general.

As a conventional hot electron transistor, a hot electron transistor comprising a collector layer, a base layer, an emitter layer, a collector barrier layer formed between the collector layer and the base layer, an emitter barrier layer formed between the base layer and the emitter layer is disclosed. This hot electron transistor is configured such that the collector barrier layer is formed by i-type germanium-silicon and the emitter barrier layer is formed by i-type aluminum gallium arsenide (low-concentration n-type gallium arsenide), in order that the height of a barrier of the collector barrier layer may be rendered lower than that of a barrier of the emitter barrier layer. In the hot electron transistor, when a prescribed bias is applied, electrons pass through the emitter barrier layer from the emitter layer due to tunneling or pass over the emitter barrier layer to reach the base layer and become hot electrons having high energy. These hot electrons pass through at a high speed without hardly scattered in the base layer (ballistic conduction) and reach the collector layer through the collector barrier layer.

In the conventional hot electron transistor, however, when electrons moves from the emitter layer to the base layer due to the tunneling, the electrons pass through the energy barrier of the emitter barrier layer and hence a large amount of current is disadvantageously difficult to flow. Thus, it is disadvantageously difficult to obtain desired high-frequency characteristic and a driving current required for a subsequent circuit.

### SUMMARY OF THE INVENTION

A hot electron transistor according to a first aspect of the present invention comprises a collector layer, a base layer, an emitter layer, a collector barrier layer formed between the collector layer and the base layer, and an emitter barrier layer formed between the base layer and the emitter layer, wherein an energy barrier between the emitter barrier layer and the emitter layer does not substantially exist and the height of an energy barrier of the collector barrier layer is lower than the height of an energy barrier of the emitter barrier layer.

A semiconductor device according to a second aspect of the present invention comprises a substrate, a transistor formed on the substrate, an interlayer dielectric film so formed on a surface of the substrate as to cover the transistor, and a hot electron transistor formed on a surface of the interlayer dielectric film, wherein the hot electron transistor includes a collector layer, a base layer, an emitter layer, a collector barrier layer formed between the collector layer and the base layer and an emitter barrier layer formed between the base layer and the emitter layer, and an energy barrier between the emitter barrier layer and the emitter layer does not substantially exist and the height of an energy barrier on an interface between the base layer and the collector barrier layer viewed from Fermi energy of the base layer is smaller than the height of an energy barrier on an interface between the base layer and the emitter barrier layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a hot electron transistor according to a first embodiment of the present invention;

FIGS. 2 and 3 are diagrams showing an energy band of a conductive band of the hot electron transistor according to the first embodiment;

FIGS. 4 to 9 are sectional views for illustrating a process for fabricating the hot electron transistor according to the first embodiment;

FIG. 10 is a sectional view showing a structure of a semiconductor device according to a second embodiment;

FIG. 11 is a sectional view showing a structure of a hot electron transistor according to a third embodiment; and

FIGS. 12 to 17 are sectional views for illustrating a process for fabricating the hot electron transistor according to the third embodiment.

### DESCRIPTION OF THE PREFERRED EMBODIMENTS

Embodiments of the present invention will be hereinafter described with reference to drawings.

### First Embodiment

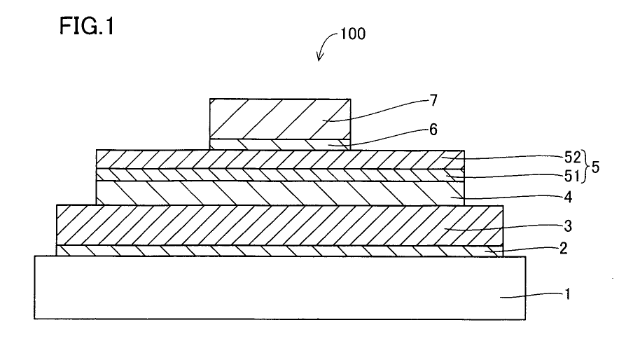

A structure of a hot electron transistor 100 according to a first embodiment of the present invention will be now described with reference to FIGS. 1 to 3.

In the hot electron transistor 100, a subcollector layer 2 made of T1 is formed on a prescribed region of a surface of a silicon substrate 1 as shown in FIG. 1. This subcollector layer 2 has a thickness of about 5 nm and is formed as an underlayer for forming an after-mentioned collector layer 3.

The collector layer 3 made of TiN is formed on a surface of the subcollector layer 2. This collector layer 3 has a thickness of about 100 nm. The collector layer 3 made of TiN has a prescribed nitrogen atom (N) concentration and a work function of about 4.7 eV.

A collector barrier layer 4 made of TiO₂ is formed on a prescribed region of a surface of the collector layer 3. This collector barrier layer 4 has a thickness of about 20 nm to about 50 nm and an electron affinity (energy difference between a bottom of a conduction band and a vacuum level) of about 4.05 eV. The collector barrier layer 4 made of TiO₂ is an example of the “collector barrier layer made of an oxide of Ti” in the present invention.

A collector side base layer 51 made of TiN is formed on a surface of the collector barrier layer 4. This collector side base layer 51 has a thickness of about 2 nm. The collector side base layer 51 made of Ti has a nitrogen atom concentration higher than that of the collector layer 3 and has a work function of about 4.3 eV. The collector side base layer 51 is an example of the “first base layer” in the present invention.

The emitter side base layer 52 made of TiN is formed on a surface of the collector side base layer 51. This emitter side base layer 52 has a thickness of about 5 nm. The emitter side base layer 52 made of TiN has a nitrogen atom concentration lower than that of the collector side base layer 51 and substantially the same as that of the collector layer 3 and a work function of about 4.7 eV. The emitter side base layer 52 is an example of the “second base layer” in the present invention. The emitter side base layer 52 and the collector side base layer 51 constitute a base layer 5.

An emitter barrier layer 6 made of TiO₂ similarly to the collector barrier layer 4 is formed on a prescribed region of a surface of the emitter side base layer 52. This emitter barrier layer 6 has a thickness of about 5 nm and an electron affinity of about 4.05 eV. The emitter barrier layer 6 made of TiO₂ is an example of the “emitter barrier layer made of an oxide of Ti” in the present invention.

An emitter layer 7 made of n-type polysilicon having a high impurity concentration is formed on a surface of the emitter barrier layer 6. This emitter layer 7 has a thickness of about 200 nm and an electron affinity of about 4.05 eV. The subcollector layer 2, the collector layer 3, the collector barrier layer 4, the base layer 5, the emitter barrier layer 6 and the emitter layer 7 constitute the hot electron transistor 100.

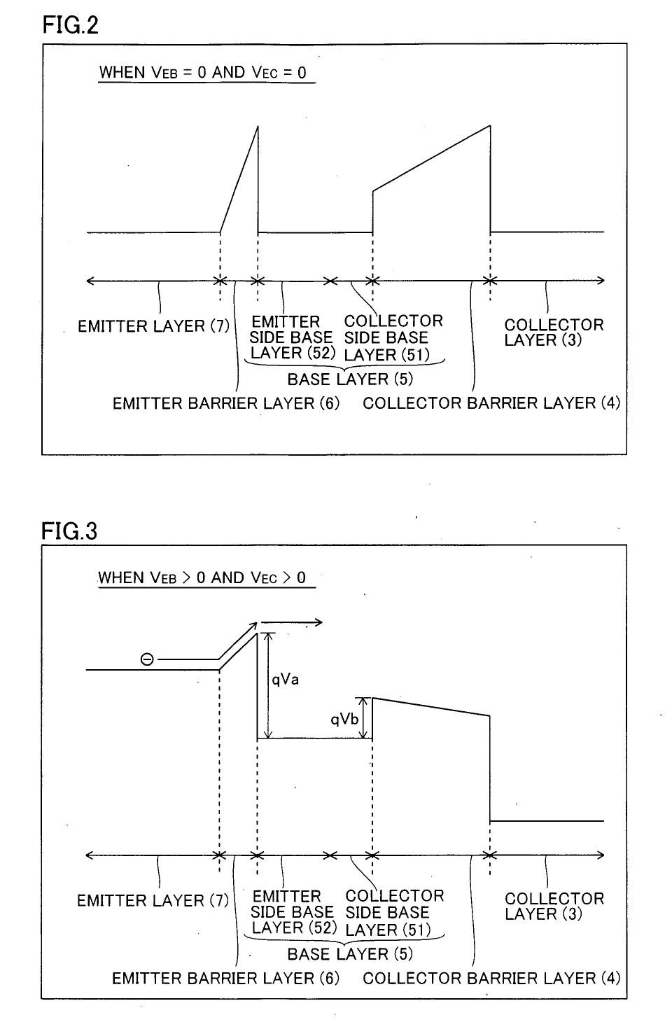

The hot electron transistor 100 is so formed as to be in an energy band state as shown in FIG. 2 when the voltage V_{EB} between the emitter layer 7 and the base layer 5=0 and the voltage V_{EC} between the emitter layer 7 and the collector layer 3=0. The hot electron transistor 100 is so formed as to be in an energy band state as shown in FIG. 3 when V_{EB}>0 and V_{EC}>0. At this time, in the hot electron transistor 100, the collector barrier layer 4 and the emitter barrier layer 6 are formed by the same material (TiO₂) and the nitrogen atom concentration of the collector side base layer 51 constituting the base layer 5 is higher than that of the emitter side base layer 52 constituting the base layer 5, so that the height qVa of the barrier of the emitter barrier layer 6 with respect to the base layer 5 (emitter side base layer 52) is higher than the height qVb of the barrier of the collector barrier layer 4 with respect to the base layer 5 (collector side base layer 51). The hot electron transistor 100 is configured such that the thickness of the base layer 5 constituting the collector side base layer 51 and the emitter side base layer 52 is smaller than the mean free path of electrons and electrons pass through the base layer 5 at a high speed without hardly scattered (ballistic conduction) and hence high frequency characteristic can be improved.

In the hot electron transistor 100, the emitter barrier layer 6 and the emitter layer 7 are so formed that the electron affinities thereof are the same (about 4.05 eV) as each other. Thus, the energy barrier between the emitter barrier layer 6 and the emitter layer 7 does not substantially exist.

An operation of the hot electron transistor 100 will be now described with reference to FIG. 3.

In a case of V_{EB}>0 and V_{EC}>0, the energy barrier between the emitter barrier layer 6 and the emitter layer 7 does not substantially exist, whereby electrons are diffused and pass from the emitter layer 7 to the emitter barrier layer 6 (diffusion current) and the electrons passing through the emitter barrier layer 6 to reach the base layer 5 (emitter side base layer 52) becomes hot electrons having high energy (qVa). These hot electrons pass through the base layer (the emitter side base layer 52 and the collector side base layer 51) at the high speed without hardly scattered (ballistic conduction) and pass through collector barrier layer 4 having the barrier height qVb to reach the collector layer 3.

A process for fabricating the hot electron transistor 100 according to the first embodiment of the present invention will be now described with reference to FIGS. 1, and 4 to 9.

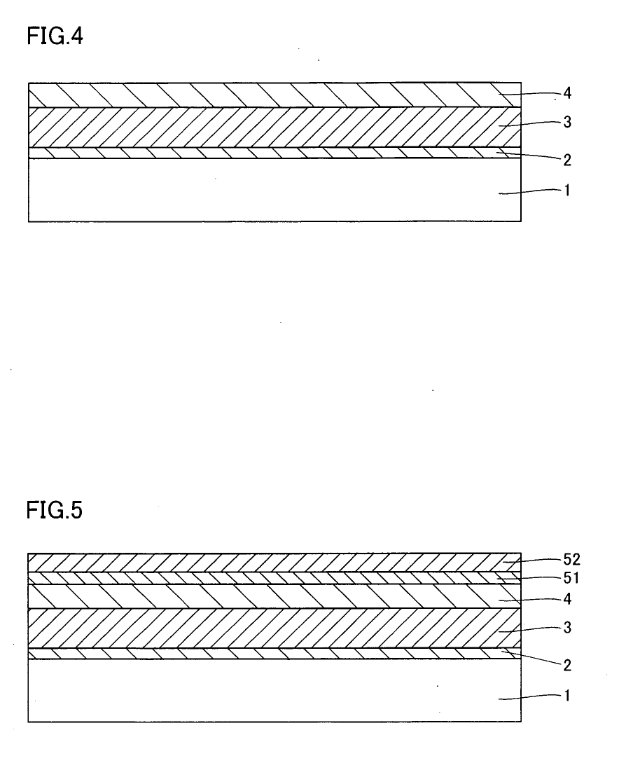

As shown in FIG. 4, the subcollector layer 2 made of Ti having a thickness of about 5 nm is formed on the surface of the silicon substrate 1 by sputtering. The collector layer 3 made of TiN having a thickness of about 100 nm is formed on the surface of the subcollector layer 2 by reactive sputtering. The ratio of the flow rate of N₂ gas to the flow rate of Ar gas is set to about 10% for forming the collector layer 3 by reactive sputtering. Thus, the collector layer 3 is so formed as to have the prescribed nitrogen atom concentration. Thereafter the collector barrier layer 4 made of TiO₂ having a thickness of about 20 nm to about 50 nm is formed on the surface of the collector layer 3 by sputtering.

As shown in FIG. 5, the collector side base layer 51 made of TiN having a thickness of about 2 nm is formed on the surface of the collector barrier layer 4 by reactive sputtering. The ratio of the flow rate of N₂ gas to the flow rate of Ar gas is set to about 20%, which is larger than the ratio of the flow rate for forming the collector layer 3, for forming the collector side base layer 51 by reactive sputtering. Thus, the collector side base layer 51 is so formed as to have the nitrogen atom concentration higher than that of the collector layer 3. The emitter side base layer 52 made of TiN having a thickness of about 5 nm is formed on the surface of the collector side base layer 51 by reactive sputtering. The ratio of the flow rate of N₂ gas to the flow rate of Ar gas is set to about 10%, which is smaller than the ratio of the flow rate for forming the collector side base layer 51 and substantially the same as that for forming the collector layer 3, for forming the emitter side base layer 52 by reactive sputtering. Thus, the emitter side base layer 52 is so formed as to have the nitrogen atom concentration lower than that of the collector side base layer 51 and substantially the same as that of the collector layer 3.

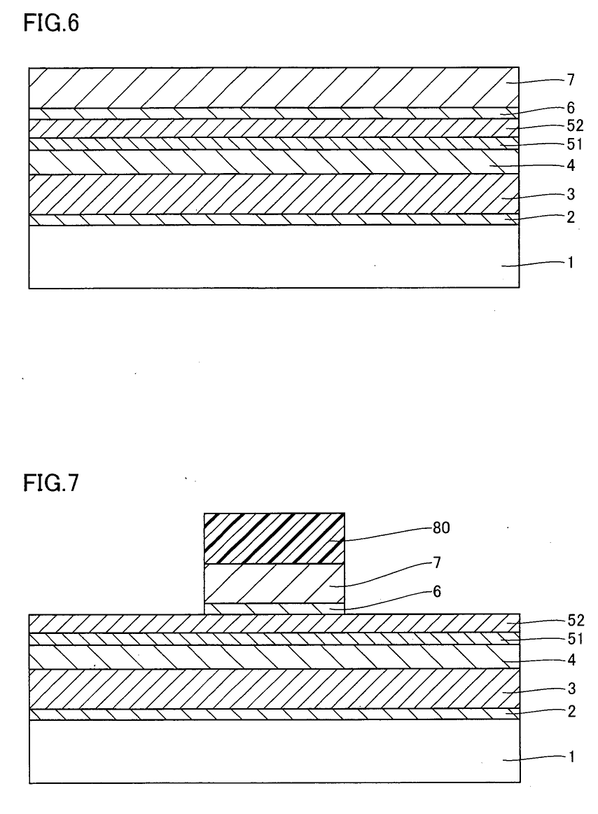

As shown in FIG. 6, the emitter barrier layer 6 made of TiO₂ similarly to the collector barrier layer 4, having a thickness of about 5 nm is formed on the surface of the emitter side base layer 52 by sputtering. Then, the emitter layer 7 made of n-type polysilicon having the high impurity concentration, having a thickness of about 200 nm is formed on the surface of the emitter barrier layer 6 by LP-CVD (low pressure chemical vapor deposition). The subcollector layer 2, the collector layer 3, the collector barrier layer 4, the collector side base layer 51, the emitter side base layer 52 and the emitter barrier layer 6 are continuously formed in the same chamber without being exposed to the air (atmosphere). In a case where the emitter layer 7 made of n-type polysilicon is formed by CVD, the subcollector layer 2, the collector layer 3, the collector barrier layer 4, the collector side base layer 51, the emitter side base layer 52 and the emitter barrier layer 6 can be formed in the same chamber. In a case where the emitter layer 7 is made of TiN by sputtering, the emitter layer can be also continuously formed in the same chamber in addition to the subcollector layer 2, the collector layer 3, the collector barrier layer 4, the collector side base layer 51, the emitter side base layer 52 and the emitter barrier layer 6.

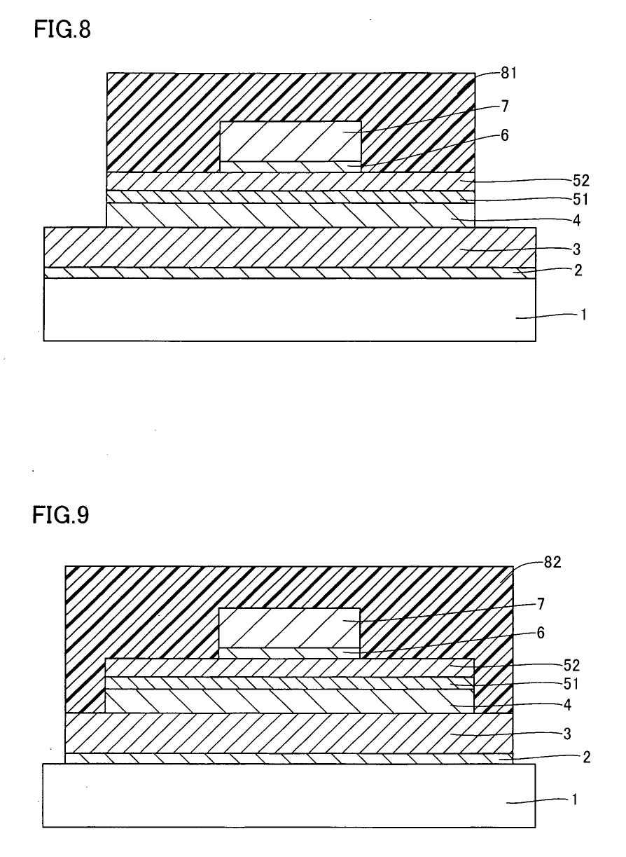

As shown in FIG. 7, a resist film 80 is formed on a prescribed region of a surface of the emitter layer 7 by photolithography. Then, the resist film 80 is employed as a mask for patterning the emitter layer 7 and the emitter barrier layer 6 by anisotropic etching. Thereafter the resist film 80 is removed.

As shown in FIG. 8, a resist film 81 is so formed on a prescribed region of the surface of the emitter side base layer 52 as to cover the emitter layer 7 and the emitter barrier layer 6 by photolithography. Then, the resist film 81 is employed as a mask for patterning the emitter side base layer 52, the collector side base layer 51 and the collector barrier layer 4 by anisotropic etching. Thereafter the resist film 81 is removed.

As shown in FIG. 9, a resist film 82 is so formed on a prescribed region of the surface of the subcollector layer 2 as to cover the emitter layer 7, the emitter barrier layer 6, the emitter side base layer 52, the collector side base layer 51 and the collector barrier layer 4 by photolithography. The resist film 82 is employed as a mask for patterning the collector layer 3 and the subcollector layer 2 by anisotropic etching. Thereafter the resist film 82 is removed, thereby forming the hot electron transistor 100 according to the first embodiment shown in FIG. 1.

According to the first embodiment, as hereinabove described, the emitter barrier layer 6 is made of TiO₂ and the emitter layer 7 is made of n-type polysilicon having the high impurity concentration. According to this structure, the emitter barrier layer 6 has an electron affinity of about 4.05 eV and the emitter layer 7 has an electron affinity of about 4.05 eV, and hence electrons are diffused and move from the emitter layer 7 to the emitter barrier layer 6 by setting to V_{EB}>0 and V_{EC}>0. Thus, the quantity of current of the hot electron transistor 100 can be increased as compared with a case where electrons pass through the collector barrier layer from the emitter layer due to tunneling. Consequently, the high-frequency characteristic of the hot electron transistor 100 can be improved. In other words, increase in a collector current reduces the charging time for filling the base layer 5 with a small amount of carriers and hence the base transit time can be reduced. Thus, a maximum cutoff frequency and a maximum oscillation frequency can be increased, and therefore a driving current can be increased. In other words, the driving current required for driving a subsequent circuit can be easily increased.

According to the first embodiment, the base layer 5 is constituted by the collector side base layer 51 having the nitrogen atom concentration higher than that of the collector layer 3 and the emitter side base layer 52 having the nitrogen atom concentration lower than that of the collector side base layer 51 and substantially the same as that of the collector layer 3. According to this structure, the work function of the collector side base layer 51 can be reduced as compared with that of the emitter side base layer 52, and hence the height qVb of the barrier closer to the base layer 5 of the collector barrier layer 4 can be lower than the height qVa of the barrier closer to the base layer 5 of the emitter barrier layer 6, also when the collector barrier layer 4 and the emitter barrier layer 6 are formed by the same material (TiO₂ in the first embodiment). Thus, the collector barrier layer 4 and the emitter barrier layer 6 can be formed by the same material and hence steps of fabricating the hot electron transistor 100 can be simplified.

According to the first embodiment, the emitter barrier layer 6 is made of TiO₂. According to this structure, the electron affinity of the emitter barrier layer 6 can be adjusted to about 4.05 eV substantially the same as the electron affinity of the emitter layer 7 made of n-type polysilicon having the high impurity concentration. Thus, no energy barrier between the emitter barrier layer 6 and the emitter layer 7 exist, and hence electrons can be diffused from the emitter layer 7 to the emitter barrier layer 6 and pass from the emitter layer 7 to the base layer 5.

According to the first embodiment, the collector layer 3 is formed on the surface of the subcollector layer 2 made of Ti for forming the collector layer 3 made of TiN. According to this structure, the collector layer 3 made of TiN can be easily formed with high reliability due to the subcollector layer 2 made of Ti having high adhesion with an insulating film.

According to the first embodiment, the collector side base layer 51 and the emitter side base layer 52 are continuously formed in the same chamber, whereby respective interfaces can be inhibited from being exposed to the air and hence the respective interfaces can be inhibited from contamination.

### Second Embodiment

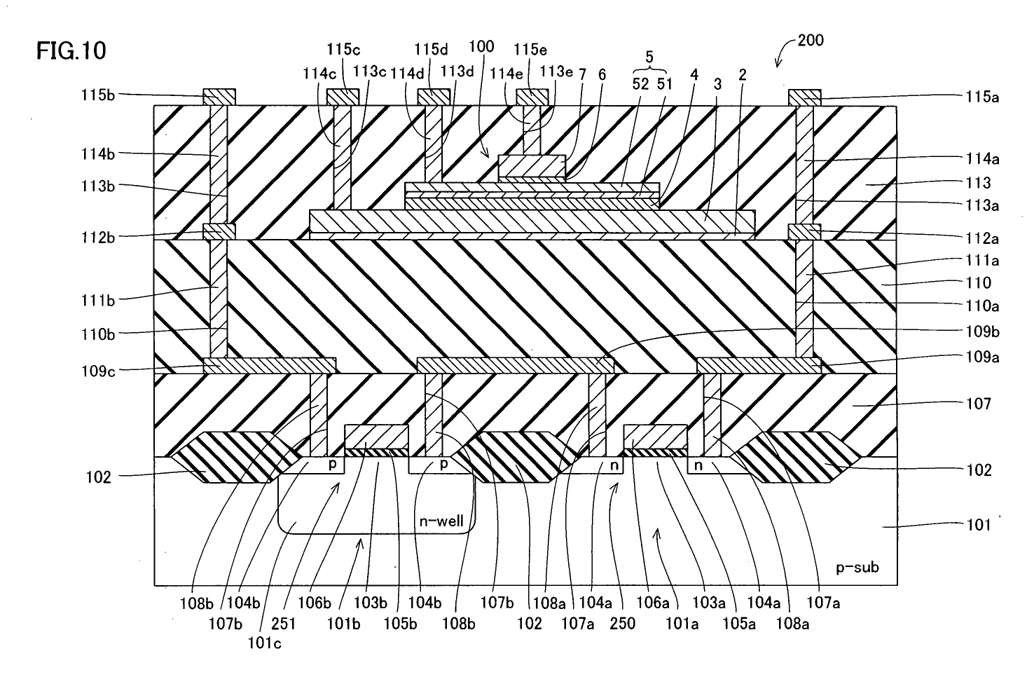

Referring to FIG. 10, a semiconductor device 200 according to a second embodiment includes the hot electron transistor 100 shown in the aforementioned first embodiment.

In the semiconductor device 200 according to the second embodiment, element isolation regions 102 having a LOCOS (local oxidation of silicon) structure are so formed on a surface of a p-type silicon substrate 101 as to surround element forming regions 101a and 101b. A pair of n-type source/drain regions 104a are so formed on the element forming region 101a at a prescribed interval as to hold a channel region 103a therebetween. A gate electrode 106a is formed on a channel region 103a through a gate insulating film 105a. The gate insulating film 105a is made of SiO₂ or the like and the gate electrode 106a is made of polysilicon or the like. The channel region 103a, the source/drain regions 104a, the gate insulating film 105a and the gate electrode 106a constitute an n-channel transistor 250. An n well region 101c is formed on the element forming region 101b. A pair of p-type source/drain regions 104b are so formed on the n well region 101c at a prescribed interval as to hold a channel region 103b therebetween. A gate electrode 106b is formed on the channel region 103b through a gate insulating film 105b. The gate insulating film 105b is made of SiO₂ or the like and the gate electrode 106b is made of polysilicon or the like. The channel region 103b, the source/drain regions 104b, the gate insulating film 105b and the gate electrode 106b constitute a p channel transistor 251.

An interlayer dielectric film 107 made of SiO₂ or the like is so formed on the surface of the p-type silicon substrate 101 as to cover the element isolation regions 102, the n-channel transistor 250 and the p channel transistor 251. The contact holes 107a and 107b are formed on regions corresponding to the source/drain regions 104a and 104b of the interlayer dielectric film 107 respectively. Plugs 108a and 108b electrically connected to the source/drain regions 104a and 104b are embedded in the contact holes 107a and 107b respectively. The plugs 108a and 108b are made of Cu, W, Al or Al, Al alloy or the like.

A wiring 109a electrically connected to one of the plugs 108a is formed on an upper surface of the one of the plugs 108a. A wiring 109b electrically connected to the other one of the plugs 108a and one of the plugs 108b is formed on an upper surface of the other one of the plugs 108a and the one of the plugs 108b. This wiring 109b is provided for electrically connecting one of the source/drain regions 104a of the n-channel transistor 250 and one of the source/drain regions 104b of the p channel transistor 251. A wiring 109c electrically connected to the other one of the plugs 108b is formed on an upper surface of the other one of the plugs 108b. The wirings 109a, 109b and 109c are made of Cu, W, Al, Al alloy or the like.

An interlayer dielectric film 110 made of SiO₂ is so formed on a surface of the interlayer dielectric film 107 as to cover the wirings 109a, 109b and 109c. The contact holes 110a and 110b are formed on regions corresponding to the wirings 109a and 109c of the interlayer dielectric film 110 respectively. Plugs 111a and 111b electrically connected to the wirings 109a and 109c are embedded in the contact holes 110a and 110b respectively. The plugs 111a and 111b are made of Cu, W, Al, Al alloy or the like.

Pad layers 112a and 112b electrically connected to the plugs 111a and 111b are formed on upper surfaces of the plugs 111a and 111b respectively. The pad layers 112a and 112b are made of Cu, W, Al, Al alloy or the like. The hot electron transistor 100 is formed on a prescribed region of a surface of the interlayer dielectric film 110.

An interlayer dielectric film 113 made of SiO₂ is so formed on the surface of the interlayer dielectric film 110 as to cover the hot electron transistor 100 and the pad layers 112a and 112b. Contact holes 113a and 113b are formed on regions corresponding to the pad layers 112a and 112b of the interlayer dielectric film 113 respectively. Contact holes 113c, 113d and 113e are formed on regions of the interlayer dielectric film 113 corresponding to the collector layer 3, the base layer 5 (emitter side base layer 52) and the emitter layer 7 respectively.

Plugs 114a and 114b electrically connected to the pad layers 112a and 112b are embedded in the contact holes 113a and 113b respectively. Plug 114c, 114d and 114e electrically connected to the collector layer 3, the base layer 5 and the emitter layer 7 are embedded in the contact holes 113c, 113d and 113e respectively. The plugs 114a to 114e are made of Cu, W, Al, Al alloy or the like. Wirings 115a to 115e electrically connected to the plugs 114a to 114e are formed on an upper surface of the plugs 114a to 114e respectively. The wirings 115a to 115e are made of Cu, W, Al, Al alloy or the like.

The remaining structure of the second embodiment is similar to that of the aforementioned first embodiment.

According to the second embodiment, as hereinabove described, the n-channel transistor 250 and the p channel transistor 251 are formed on the p-type silicon substrate 101 and the hot electron transistor 100 is formed on the surface of the interlayer dielectric film 110. According to this structure, the n-channel transistor 250 and the p channel transistor 251 can be inhibited from interfering with the hot electron transistor 100 through the substrate as a high-frequency transistor.

The remaining effects of the second embodiment are similar to those of the aforementioned first embodiment.

### Third Embodiment

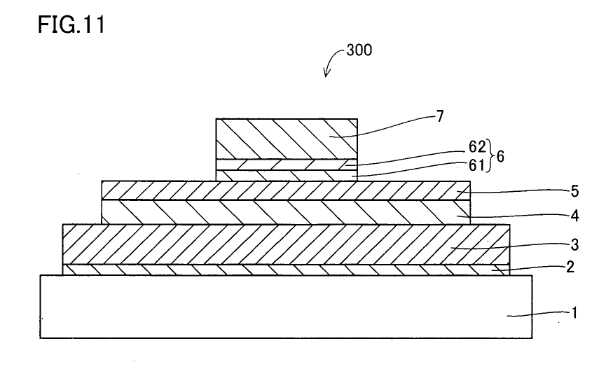

Referring to FIG. 11, a hot electron transistor 300 according to a third embodiment comprises an emitter barrier layer 6 of a two-layer structure having different crystal structures dissimilarly to the aforementioned first embodiment.

The emitter barrier layer 6 of the hot electron transistor 300 according to the third embodiment is formed by a base side emitter barrier layer 61 and an emitter side emitter barrier layer 62 formed by the same material (TiO₂ in the third embodiment), as shown in FIG. 11. More specifically, the base side emitter barrier layer 61 has a crystal structure of anatase phase having a thickness of about 2 nm. The emitter side emitter barrier layer 62 has a crystal structure of rutile phase having a thickness of about 3 nm. A collector barrier layer 4 according to the third embodiment is formed by TiO₂, which is the same material as that of the emitter barrier layer 6 and has the crystal structure of the rutile phase similarly to the emitter side emitter barrier layer 62. Thus, an energy barrier of the collector barrier layer 4 is relatively lower than an energy barrier of the emitter barrier layer 6. A base layer 5 according to the third embodiment is formed by TiN while being formed by a single layer structure. The base side emitter barrier layer 61 and the emitter side emitter barrier layer 62 are examples of the “second emitter barrier layer” and the “first emitter barrier layer” in the present invention respectively.

The remaining structure and an operation of the hot electron transistor 300 according to the third embodiment is similar to those of the hot electron transistor 100 according to the aforementioned first embodiment.

A process for fabricating the hot electron transistor 300 according to the third embodiment of the present invention will be now described with reference to FIGS. 11 to 17.

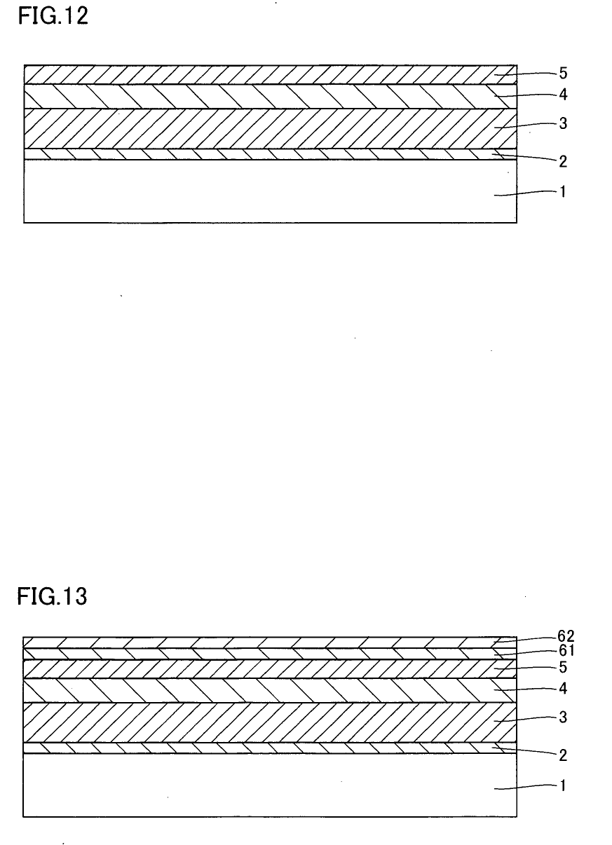

As shown in FIG. 12, a subcollector layer 2 made of Ti having a thickness of about 5 nm is formed on a surface of a silicon substrate 1 by sputtering, similarly to the first embodiment. Then a collector layer 3 made of TiN having a thickness of about 100 nm is formed on a surface of the subcollector layer 2 by reactive sputtering. The ratio of the flow rate of N₂ gas to the flow rate of Ar gas is set to about 10% for forming the collector layer 3 by reactive sputtering. Thus, the collector layer 3 is so formed as to have a prescribed nitrogen atom concentration. Thereafter the collector barrier layer 4 made of TiO₂ having a thickness of about 20 nm to about 50 nm is formed on a surface of the collector layer 3 by sputtering. At this time, a substrate temperature is set to about 200° C. and a sputtering atmosphere pressure employing a gas mixture of Ar and O is set to about 0.1 Pa. Thereafter the base layer 5 made of TiN having a thickness of about 10 nm is formed by reactive sputtering. The forming conditions of the base layer 5 by reactive sputtering are similar to those of the aforementioned collector layer 3.

As shown in FIG. 13, the base side emitter barrier layer 61 made of TiO₂ having a thickness of about 2 nm is formed on a surface of the base layer 5 by sputtering. At this time, the base side emitter barrier layer 61 is formed under a sputtering atmosphere pressure of about 1 Pa. Thus, the base side emitter barrier layer 61 is so formed as to be the anatase phase. Then, the emitter side emitter barrier layer 62 is formed by reactive sputtering under conditions identical with those of the collector barrier layer 4. Thus, the emitter side emitter barrier layer 62 is formed by the rutile phase. At this time, the thickness of the emitter side emitter barrier layer 62 is about 3 nm.

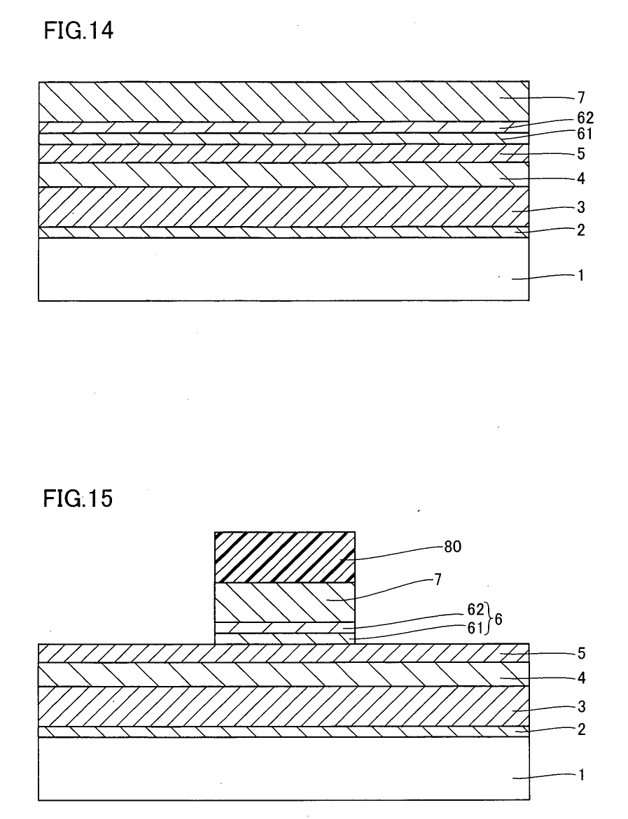

As shown in FIG. 14, an emitter layer 7 made of n-type polysilicon having a high impurity concentration is formed on a surface of the emitter barrier layer 6 by LP-CVD (low pressure chemical vapor deposition). This emitter layer 7 has a thickness of about 200 nm. The subcollector layer 2, the collector layer 3, the collector barrier layer 4, the base layer 5, the base side emitter barrier layer 61 and the emitter side emitter barrier layer 62 are continuously formed in the same chamber without being exposed to the air (atmosphere). These layers made of TiN and TiO₂ can be formed in the same chamber by changing the growth condition or the atmosphere gas.

As shown in FIG. 15, a resist film 80 is formed on a prescribed region of a surface of the emitter layer 7 by photolithography. Then, the resist film 80 is employed as a mask for patterning the emitter layer 7 and the emitter barrier layer 6 by anisotropic etching. Thereafter the resist film 80 is removed.

As shown in FIG. 16, a resist film 81 is so formed on a prescribed region of the surface of the base layer 5 by photolithography as to cover the emitter layer 7 and the emitter barrier layer 6. Then, the resist film 81 is employed as a mask for patterning the base layer 5 and the collector barrier layer 4 by anisotropic etching. Thereafter the resist film 81 is removed.

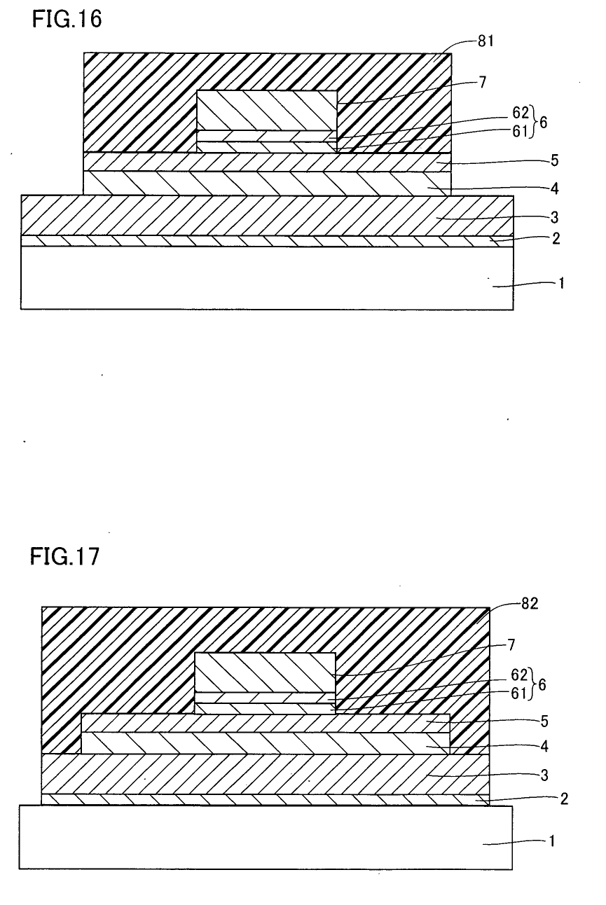

As shown in FIG. 17, a resist film 82 is so formed on a prescribed region of the surface of the subcollector layer 2 by photolithography as to cover the emitter layer 7, the emitter barrier layer 6, the base layer 5 and the collector barrier layer 4. Then, the resist film 82 is employed as a mask for patterning the collector layer 3 and the subcollector layer 2 by anisotropic etching. Thereafter the resist film 82 is removed, thereby forming the hot electron transistor 300 shown in FIG. 11.

According to the third embodiment, as hereinabove described, the emitter barrier layer 6 is formed by the two-layer structure of the base side emitter barrier layer 61 having the crystal structure of the anatase phase and the emitter side emitter barrier layer 62 having the crystal structure of the rutile phase when the collector barrier layer 4 and the emitter barrier layer 6 are formed by the same material. Also in a case of this structure, the work function between the collector layer 3 and the base layer 5 can be smaller than the work function between the emitter layer 7 and the base layer 5. In other words, the height of the energy barrier closer to the base layer 3 of the collector barrier layer 4 can be lower than the height of the energy barrier closer to the base layer 5 of the emitter barrier layer 6 (base side emitter barrier layer 61).

According to the third embodiment, the collector barrier layer 4, the base layer 5, the base side emitter barrier layer 61 and the emitter side emitter barrier layer 62 is formed by the same metal material (Ti), whereby these layers can be formed in the same chamber. Therefore, steps of fabricating the hot electron transistor 300 can be simplified.

The remaining effects of the third embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the collector side base layer 51, the emitter side base layer 52 and the collector layer 3 are formed by TiN in the aforementioned first and second embodiments, the present invention is not restricted to this but the collector side base layer, the emitter side base layer and the collector layer may be alternatively formed by other metal nitride such as TaN.

While the base layer 5 constituted by the emitter side base layer 52 and the collector side base layer 51 is formed in the aforementioned first and second embodiments the present invention is not restricted to this but one base layer may be alternatively formed such that the nitrogen atom concentration on a side of the collector layer is higher than the nitrogen atom concentration on a side of the emitter layer.

While the subcollector layer 2, the collector barrier layer 4 and the emitter barrier layer 6 are formed by sputtering and the collector layer 3, the collector side base layer 51 and the emitter side base layer 52 are formed by reactive sputtering in the aforementioned first and second embodiments, the present invention is not restricted to this but the subcollector layer, the collector barrier layer, the emitter barrier layer, the collector layer, the collector side base layer and the emitter side base layer may be alternatively formed by CVD.

While the subcollector layer 2, the collector layer 3, the collector barrier layer 4, the collector side base layer 51, the emitter side base layer 52, the emitter barrier layer 6 and the emitter layer 7 are continuously formed in the same chamber in the aforementioned first and second embodiments, the present invention is not restricted to this but the layers may be alternatively successively formed in a plurality of different chambers respectively.

While the collector barrier layer 4 and the emitter barrier layer 6 are formed by TiO₂ in the aforementioned first to third embodiments, the present invention is not restricted to this but the collector barrier layer and the emitter barrier layer may be alternatively formed by other metal oxide such as TaO₂.

While the emitter layer 7 made of n-type polysilicon having the high impurity concentration is formed in the aforementioned first to third embodiments, the present invention is not restricted to this but an emitter layer made of other metal nitride such as TiN may be alternatively formed. In this case, the work function of the emitter layer is preferably adjusted to be substantially the same as the electron affinity of the emitter barrier layer, and the work function of TiN or the like tends to decrease (narrow) when the composition ratio of N is high.

While the thickness of the base layer 5 is smaller than the mean free path of the electrons in the aforementioned first to third embodiments, the present invention is not restricted to this but the thickness of the base layer may be alternatively larger than the mean free path of the electrons so far as a prescribed number or more of electrons capable of ballistic conduction exist in the base layer and the number of electrons moving out from the emitter layer and not reaching the collector layer is at most about one severalth to one hundredth.

While the interface of the emitter layer with the emitter barrier layer is formed by n-type polysilicon having the high impurity concentration in the aforementioned first to third embodiments, the present invention is not restricted to this but the interface of the emitter layer with the emitter barrier layer may be alternatively formed by an alloy or silicide having a work function coincident with a bottom of the conductive band of silicon. Alternatively, the interface of the emitter layer with the emitter barrier layer may be formed by semiconductor such as SiC, having an electron affinity smaller than Si. In this case, also when an oxide having a dielectric constant smaller than that of TiO₂ is employed as the emitter barrier layer, the oxide is unlikely to become a potential barrier to electrons and is likely to feed a current.

While the plugs 108a, 108b, 111a, 111b and 114a to 114e are embedded in the contact holes 107a, 107b, 110a, 110b and 113a to 113e in the aforementioned second embodiment, the present invention is not restricted to this but barrier metal layers made of Ti, having higher electric conductivity and capable of inhibiting the plugs from diffusing in the interlayer dielectric films may be alternatively formed on inner peripheral surfaces of the contact holes and the plugs may be alternatively formed in the contact holes through the barrier metal layers.

While the semiconductor device including the hot electron transistor shown in the first embodiment is shown in the aforementioned second embodiment, the present invention is not restricted to this but the hot electron transistor shown in the third embodiment may be applied to the semiconductor device according to the second embodiment.

While the base side emitter layer, the emitter side emitter layer and the collector layer are formed by TiN in the aforementioned third embodiment, the present invention is not restricted to this but the collector side base layer, the emitter side base layer and the collector layer may be alternatively formed by other metal nitride such as TaN.

What is claimed is:

1. A hot electron transistor comprising:
a collector layer;
a base layer;
an emitter layer;
a collector barrier layer formed between said collector layer and said base layer; and
an emitter barrier layer formed between said base layer and said emitter layer, wherein
an energy barrier between said emitter barrier layer and said emitter layer does not substantially exist and the height of an energy barrier of said collector barrier layer is lower than the height of an energy barrier of said emitter barrier layer.

2. The hot electron transistor according to claim 1, wherein
said base layer is made of a metal nitride.

3. The hot electron transistor according to claim 1, wherein
said base layer contains nitrogen atoms, and
said base layer is formed such that the nitrogen atom concentration on a side of said collector layer is higher than the nitrogen atom concentration on a side of said emitter layer.

4. The hot electron transistor according to claim 3, wherein
said base layer includes a first base layer and a second base layer,
said first base layer is formed on the side of said collector layer and has a first nitrogen atom concentration, and
said second base layer is formed on the side of said emitter layer and has a second nitrogen atom concentration lower than said first nitrogen atom concentration.

5. The hot electron transistor according to claim 1, wherein
said collector barrier layer and said emitter barrier layer are made of the same metal oxide.

6. The hot electron transistor according to claim 1, wherein
an interface of said emitter layer with said emitter barrier layer is made of either silicon or a metal nitride.

7. The hot electron transistor according to claim 1, wherein
an interface of said emitter barrier layer with said emitter layer and an interface of said emitter barrier layer with said base layer are made of materials having different energy barrier heights respectively.

8. The hot electron transistor according to claim 7, wherein
said emitter barrier layer and said collector barrier layer are made of the same material, and the interface of said emitter barrier layer with said emitter layer and said collector barrier layer have the same crystal structure.

9. The hot electron transistor according to claim 7, wherein
the interface of said emitter barrier layer with said emitter layer and the interface of said emitter barrier layer with said base layer have different crystal structures respectively.

10. The hot electron transistor according to claim 1, wherein
said base layer is made of TiN and said emitter barrier layer and said collector barrier layer are made of an oxide of Ti.

11. A semiconductor device comprising:
a substrate;
a transistor formed on said substrate;
an interlayer dielectric film so formed on a surface of said substrate as to cover said transistor; and
a hot electron transistor formed on a surface of said interlayer dielectric film, wherein
said hot electron transistor includes a collector layer, a base layer, an emitter layer, a collector barrier layer formed between said collector layer and said base layer and an emitter barrier layer formed between said base layer and said emitter layer, and
an energy barrier between said emitter barrier layer and said emitter layer does not substantially exist and the height of an energy barrier on an interface between said base layer and said collector barrier layer viewed from Fermi energy of said base layer is smaller than the height of an energy barrier on an interface between said base layer and said emitter barrier layer.

12. The semiconductor device according to claim 11, wherein
said base layer of said hot electron transistor is made of a metal nitride.

13. The semiconductor device according to claim 11, wherein
said base layer of said hot electron transistor contains nitrogen atoms, and
said base layer is formed such that the nitrogen atom concentration on a side of said collector layer is higher than the nitrogen atom concentration on a side of said emitter layer.

14. The semiconductor device according to claim 13, wherein
said base layer of said hot electron transistor includes a first base layer and a second base layer,
said first base layer is formed on the side of said collector layer and has a first nitrogen atom concentration, and
said second base layer is formed on the side of said emitter layer and has a second nitrogen atom concentration lower than said first nitrogen atom concentration.

15. The semiconductor device according to claim 11, wherein
said collector barrier layer and said emitter barrier layer of said hot electron transistor are made of the same metal oxide.

16. The semiconductor device according to claim 11, wherein
an interface of said emitter layer with said emitter barrier layer of said hot electron transistor is made of either silicon or a metal nitride.

17. The semiconductor device according to claim 11, wherein
an interface of said emitter barrier layer with said emitter layer of said hot electron transistor and an interface of said emitter barrier layer with said base layer of said hot electron transistor are made of materials having different energy barrier heights respectively.

18. The semiconductor device according to claim 17, wherein
said emitter barrier layer and said collector barrier layer of said hot electron transistor are made of the same material, and the interface of said emitter barrier layer with said emitter layer and said collector barrier layer have the same crystal structure.

19. The semiconductor device according to claim 17, wherein
the interface of said emitter barrier layer with said emitter layer of said hot electron transistor and the interface of said emitter barrier layer with said base layer of said hot electron transistor have different crystal structures respectively.

20. The semiconductor device according to claim 11, wherein
said base layer of said hot electron transistor is made of TiN and said emitter barrier layer and said collector barrier layer of said hot electron transistor are made of an oxide of Ti.
